(19) United States
(12) Patent Application Publication
(10) Pub. No.: US 2014/0358465 A1
(43) Pub. Date: Dec. 4, 2014

(54) YIELD ANALYSIS SYSTEM AND METHOD USING SENSOR DATA OF FABRICATION EQUIPMENT

(71) Applicant: SAMSUNG SDS CO., LTD., Seoul (KR)

(72) Inventors: Kae Young SHIN, Seoul (KR); Jong Seung LIM, Seoul (KR); Dae Jung AHN, Yongin-si (KR); Seung Jai MIN, Seoul (KR); Jong Ho LEE, Seoul (KR)

(73) Assignee: SAMSUNG SDS CO., LTD., Seoul (KR)

(21) Appl. No.: 14/011,873

(22) Filed: Aug. 28, 2013

(30) Foreign Application Priority Data
May 31, 2013 (KR) 10-2013-0062300

(51) Int. Cl. H01L 21/66

(52) U.S. Cl. CPC H01L 22/20
USPC 702/82; 702/81

(57) ABSTRACT

A system and method for analyzing a product fabrication process are disclosed. A product yield analysis system according to an exemplary embodiment of the present disclosure includes a data extraction unit that extracts sensor data from a plurality of sensors arranged in equipment for fabricating a product, a reference signal generation unit that generates a reference signal for each of the plurality of sensors from the sensor data, and a sensor detection unit that detects one or more sensors having a correlation with a yield of the product using the sensor data and the reference signal.

### CROSS-REFERENCE TO RELATED APPLICATION

This application claims priority to and the benefit of Republic of Korea Patent Application No. 10-2013-0062300, filed on May 31, 2013, the disclosure of which is incorporated herein by reference in its entirety.

### BACKGROUND

1. Field

Embodiments of the present disclosure relate to techniques for analyzing a product fabrication process.

2. Discussion of Related Art

In the field of equipment for semiconductor or display fabrication, an equipment analysis system such as a Fault Detection and Classification (FDC) system is commonly employed to analyze problems that may occur in fabrication process. The equipment analysis system uses various data from sensors arranged in the semiconductor device fabrication equipment to analyze and control a process or an apparatus having an effect on the yield of semiconductor devices.

In a related approach for analyzing a root cause of product defects, a determination may be based on Work-In-Progress (WIP) information regarding products which are found to be defective (i.e., bad) or non-defective (i.e., good). In such an approach, the ratio of good products to bad products is calculated on a per-facility basis. Also, in such an approach, the between-ratio differences may be ranked in descending order and, accordingly, a suspected facility or chamber may be pointed out as a cause of the defects. However, this conventional root cause analysis approach is hardly applicable when the defective product rate is significantly low, or when an in-line facility is provided for product fabrication, or when two or more causes contribute to a product defect. In an alternative root cause analysis approach, a defect cause may be identified based on a significant difference between a good product and a bad product, for example, by using a summary value (FDC Summary Data) such as an average of sensor data recorded in an equipment analysis system. However, according to this approach, since the analysis is based on the representative value, which summarizes the entire sensor data, but does not use the original sensor data having time series characteristics, a change in the pattern of the sensor data cannot be reflected in the result, and the analysis result is therefore likely to be distorted.

### SUMMARY

One or more exemplary embodiments may overcome the above disadvantages and other disadvantages not described above. However, it is understood that one or more exemplary embodiments are not required to overcome the disadvantages described above, and may not overcome any of the problems described above.

Embodiments of the present disclosure are directed to yield analysis for using sensor data from facilities through which a product is fabricated so that if the product has a defect, a facility suspected of causing the defect can be identified with a degree of accuracy.

According to an exemplary embodiment, a yield analysis system includes a computer, executing program commands, and implementing: a data extraction unit configured to extract respective sensor data from each sensor of a plurality of sensors arranged in equipment for fabricating a product; a reference signal generation unit configured to generate a reference signal, for said each sensor, from the sensor data; and a sensor detection unit configured to detect one or more sensors of the plurality of sensors having a correlation, with a yield of the product, using the sensor data and the reference signal.

In an aspect of the yield analysis system, the data extraction unit is further configured to carry out one of a correction operation and a filter operation with respect to the sensor data, based on a number of values missing from the sensor data.

In an aspect of the yield analysis system, the data extraction unit is further configured to remove the respective sensor data, extracted from a specific sensor of the plurality of sensors, when the number of values missing from the respective extracted sensor data exceeds a predetermined threshold value.

In an aspect of the yield analysis system, the data extraction unit is further configured to remove the sensor data related to a specific product when the number of values missing from the sensor data related to the specific product exceeds a predetermined threshold value.

In an aspect of the yield analysis system, the sensor detection unit is further configured to calculate a distance between the respective sensor data and the reference signal, and detects one or more of the plurality of sensors having a correlation with the yield of the product based on the calculated distance.

In an aspect of the yield analysis system, there is also provided a preprocessing unit configured to perform preprocessing with respect to the sensor data and the reference signal, including at least one of a compression operation, a normalization operation, and a symbolization operation.

In an aspect of the yield analysis system, the preprocessing unit is further configured to compress the sensor data by: grouping the sensor data into a plurality of time intervals; and calculating a representative value of the sensor data in each grouping time interval.

In an aspect of the yield analysis system, the representative value is one of an average value and a median value of the sensor data, in each grouped time interval.

In an aspect of the yield analysis system, the reference signal generation unit is further configured to: generate the reference signal by grouping the compressed sensor data from each sensor into one of a good group and a bad group, based on information indicating whether the product is determined to be defective; and calculate one of an average value and a median value of the sensor data belonging to the good group, for each time interval.

In an aspect of the yield analysis system, the reference signal generation unit is further configured to remove an outlier from the good group, before generating the reference signal.

In an aspect of the yield analysis system, at least one of a data start time and a data end time of the outlier is not included in a predetermined normal range.

In an aspect of the yield analysis system, the normal range is calculated using at least one of an average value and a standard deviation of one of the data start time and the data end time of the sensor data included in the good group.

In an aspect of the yield analysis system, the preprocessing unit is further configured to: normalize the compressed sensor data using an average and a variance of the reference signal; and convert a sensor value of the normalized sensor data and the reference signal to a plurality of symbols according to a predetermined sensor value range.

In an aspect of the yield analysis system, the sensor detection unit is further configured to generate a decision tree by: generating a distance table using the symbolized sensor data and reference signal, and yield decision information regarding the product; and applying a classification and regression tree (CART) algorithm to the distance table.

In an aspect of the yield analysis system, the sensor detection unit is further configured to detect, as a sensor having a correlation with the yield of the product, a sensor for which a Gini index, derived from the application of the CART algorithm, is at least a predetermined value.

According to another exemplary embodiment, a yield analysis method includes: extracting, by a data extraction unit, sensor data from each sensor of a plurality of sensors arranged in equipment for fabricating a product; generating, by a reference signal generation unit, a reference signal for said each sensor, from the sensor data; and detecting, by a sensor detection unit, one or more sensors of the plurality of sensors having a correlation with a yield of the product, using the sensor data and the reference signal.

In an aspect of the yield analysis method, the extracting of the sensor data includes carrying out one of a correcting operation and a filtering operation with respect to the sensor data, based on a number of values missing from the sensor data.

In an aspect of the yield analysis method, the method also includes removing the sensor data extracted, from a specific sensor of the plurality of sensors, when the number of values missing from the respective extracted sensor data exceeds a predetermined threshold value.

In an aspect of the yield analysis method, the method also includes removing the sensor data related to the specific product when the number of values missing from the sensor data related to the specific product exceeds a predetermined threshold value.

In an aspect of the yield analysis method, the detecting of the sensors includes calculating a distance between the respective sensor data and the reference signal, and detecting one or more of the plurality of sensors having a correlation with the yield of the product based on the calculated distance.

In an aspect of the yield analysis method, the method also includes, after the extracting of the sensor data and before the generating of the reference signal, compressing the extracted sensor data using a preprocessing unit.

In an aspect of the yield analysis method, the compressing of the sensor data includes: grouping the sensor data into a plurality of time intervals; and calculating a representative value of the sensor data in each grouping time interval.

In an aspect of the yield analysis method, the representative value is one of an average value and a median value of the sensor data, in each grouped time interval.

In an aspect of the yield analysis method, the generating of the reference signal for each sensor includes: grouping the compressed sensor data from each sensor into one of a good group and a bad group, based on information indicating whether the product is determined to be defective; and calculating one of an average value and a median value of the sensor data belonging to the good group, for each time interval.

In an aspect of the yield analysis method, the grouping of the compressed sensor data includes removing an outlier from the good group.

In an aspect of the yield analysis method, at least one of a data start time and a data end time of the outliner is not included in a predetermined normal range.

In an aspect of the yield analysis method, the normal range is calculated using at least one of an average value and a standard deviation of one of the data start time and the data end time of the sensor data included in the good group.

In an aspect of the yield analysis method, the method also includes, before the detecting of the one or more sensors: normalizing, by the preprocessing unit, the compressed sensor data using an average and a variance of the reference signal; and converting, by the preprocessing unit, a sensor value of the normalized sensor data and the reference signal to a plurality of symbols according to a predetermined sensor value range.

In an aspect of the yield analysis method, the detecting of the one or more sensors includes: generating a distance table using the symbolized sensor data and reference signal and yield decision information regarding the product; and applying a CART (Classification And Regression Tree) algorithm to the distance table.

In an aspect of the yield analysis method, the detecting of the one or more sensors further includes detecting, as a sensor having a correlation with the yield of the product, a sensor for which a Gini index derived from the application of the CART algorithm is at least a predetermined value.

According to yet another exemplary embodiment, a device that may be used for yield analysis includes: one or more processors; a memory; and one or more programs stored in the memory, the one or more programs being configured to be executed by the one or more processors. The one or more programs enable the one or more processors to carry out operations, including: extracting sensor data from each sensor of a plurality of sensors arranged in equipment for fabricating a product; generating a reference signal for said each sensor from the sensor data; and detecting one or more sensors of the plurality of sensors having a correlation with a yield of the product, using the sensor data and the reference signal.

### BRIEF DESCRIPTION OF THE DRAWINGS

The above and other objects, features and advantages of the exemplary embodiments the present disclosure will become more apparent to those skilled in the art from the following detailed description when taken in conjunction with the accompanying drawings, in which:

FIG. 1 is a block diagram for illustrating a yield analysis system 100 which uses fabrication process data according to an exemplary embodiment of the present disclosure; and

FIG. 2 is a flowchart for illustrating a yield analysis method 200 which uses fabrication process data according to an exemplary embodiment of the present disclosure.

### DETAILED DESCRIPTION OF EXEMPLARY EMBODIMENTS

Exemplary embodiments of the present disclosure will be described below with reference to the accompanying drawings. However, the exemplary embodiments are only illustrative and the present disclosure is not limited thereto.

In the following detailed description, various details known to those familiar with this field may be omitted to avoid obscuring the gist of the present disclosure. Also, terminology described below is defined with reference to functions in the present disclosure and may vary according to a user's or an operator's intention or usual practice. Therefore, the meanings of the terminology should be interpreted based on the overall context of the present specification.

The spirit of the present disclosure is determined by the claims, and the following exemplary embodiments are provided to effectively describe the spirit of the present disclosure to those skilled in the art.

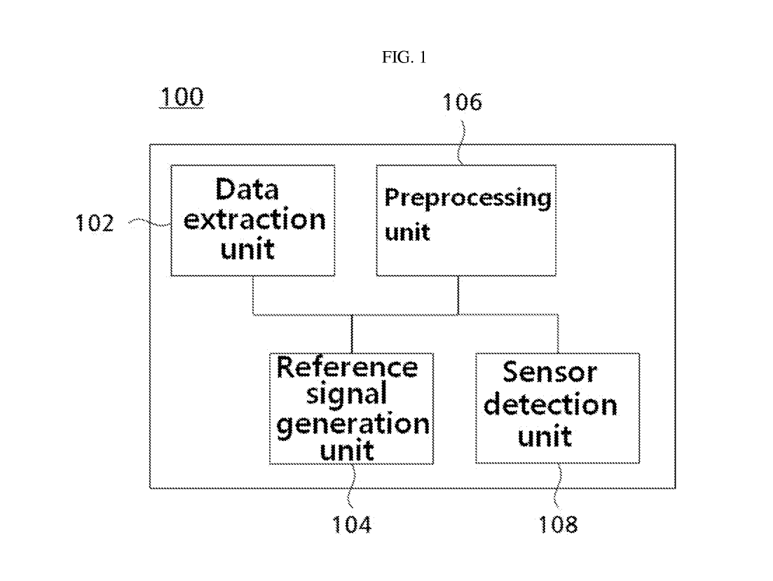

FIG. 1 is a block diagram for illustrating a yield analysis system 100 which uses fabrication process data according to an exemplary embodiment of the present disclosure. In exemplary embodiments of the present disclosure, the yield analysis system 100 analyzes fabrication process data and information regarding whether a product is determined to be non-defective or defective so that a process component having an effect on a yield of the product can be recognized. Hereinafter, exemplary embodiments of the present disclosure will be described with regard to a process of fabricating a semiconductor device. However, it should be noted that the present disclosure may also be applied, with suitable modification, to any products produced through a predefined process using fabrication equipment. In other words, even when only the term “semiconductor device” is described below, such a semiconductor device should be interpreted as “a semiconductor device as an example of a product” according to the present disclosure.

In exemplary embodiments of the present disclosure, the yield analysis system 100 is configured to acquire data from various sensors arranged in equipment for fabricating a product such as a semiconductor device and, based on the acquired sensor data, detect a suspected facility or process that may cause a defect of the fabricated product. In embodiments of the present disclosure, the semiconductor device refers to a product fabricated at a fabrication facility (FAB) for a semiconductor or a display. For example, a silicon wafer or a glass wafer may be the semiconductor device in the examples below.

The product yield analysis system 100 according to an exemplary embodiment of the present disclosure includes a data extraction unit 102, a reference signal generation unit 104, a preprocessing unit 106, and a sensor detection unit 108, as shown in FIG. 1.

The data extraction unit 102 acquires data from a plurality of sensors arranged in equipment for fabricating a product such as a semiconductor device. The reference signal generation unit 104 generates a reference signal for each of the plurality of sensors from the sensor data acquired by the data extraction unit 102. The preprocessing unit 106 performs a preprocessing operation to reduce the volume of the sensor data and that of the reference signal and remove the noise from the sensor data and that from the reference signal. The sensor detection unit 108 calculates a distance between the preprocessed sensor data and the preprocessed reference signal, and detects one or more sensors having a correlation with a yield of the product using a calculated distance.

Hereinafter, the respective components of the product yield analysis system 100 configured as above will be described in more detail.

Data Extraction

The data extraction unit 102 extracts, from fabrication equipment such as equipment for fabricating a semiconductor device or the like, raw data to be analyzed. It processes the raw data into data having a format suitable for analysis. First, the data extraction unit 102 acquires sensor data from a plurality of sensors arranged in the fabrication equipment.

In this case, the sensors are provided for detecting a state change that occurs in the course of fabricating a product at the fabrication equipment, and may be, for example, temperature sensors or pressure sensors arranged in a facility in which a specific process is applied. In other words, the temperature sensor or the pressure sensor may be configured to sense how the temperature or the pressure of the equipment changes over time during the product fabrication. The data extraction unit 102 extracts, from such sensors, the sensor data for each process conducted in the product fabrication equipment, for each sub-process of each process, or for each chamber of the product fabrication equipment.

Further, the data extraction unit 102 may acquire information regarding a finally determined yield of the product, e.g., a semiconductor device, produced by the fabrication equipment (or information regarding whether the product is determined to be defective or non-defective), and store the information in conjunction with the sensor data. The information regarding the determined yield may be acquired, for example, from an apparatus arranged in the fabrication equipment for electric die sorting (EDS). In other words, since the data extraction unit 102 stores the sensor data, sensed by each sensor during the fabrication of a product, in conjunction with information regarding whether the product is determined to be non-defective or defective, the data extraction unit 102 may trace how a defect rate of the product changes according to a change in the sensor data for a subsequent data analysis process.

Meanwhile, due to various reasons, such as an error in data collection, a sensing error, or malfunction of the sensor, there may be values missing from the sensor data that was extracted by the data extraction unit 102. Accordingly, the data extraction unit 102 is configured to correct or filter the sensor data in consideration of the number of values missing from the sensor data.

For example, when the number of values missing from the sensor data extracted from a specific sensor exceeds a predetermined threshold value, the data extraction unit 102 may remove the sensor data extracted from that specific sensor, so that a sensor value from the specific sensor can be excluded from a subsequent analysis. Further, the data extraction unit 102 may be configured to remove the entire sensor data related to the specific product, i.e., the sensor data generated in the course of fabricating the specific product, when the number of values missing from the sensor data related to the specific product exceeds a predetermined threshold value. In other words, in an exemplary embodiment of the present disclosure, the data extraction unit 102 is configured to exclude all the sensor data related to a specific sensor, or all the data related to a specific product, from being analyzed when an excessive number of values are missing from the sensor data, so that errors in the analysis results may be minimized.

On the other hand, when some values are missing from the sensor data but the number of the missing values does not exceed the predetermined threshold value, the data extraction unit 102 may correct the missing values using preceding and/or subsequent sensor data. For example, the data extraction unit 102 may correct a missing value using the following equation (1):

$$y = {y}_{a} + ( {y}_{b} - {y}_{a} ) \frac{x - {x}_{a}}{{x}_{b} - {x}_{a}} \qquad [ Equation 1 ]$$

where y denotes the missing value, x denotes the time corresponding to the missing value, yₐ denotes the sensor value immediately preceding the missing value, y_{b} denotes the sensor value immediately following the missing value, and xₐ and x_{b} respectively denote the time when the values of yₐ and y_{b} are sensed. However, the missing value correction equation of Equation (1) is only illustrative, and various other methods for supplying the missing value may be applied. In other words, it should be noted that embodiments of the present disclosure are not limited to a specific missing value correction algorithm.

Data Preprocessing and Reference Signal Generation

With the sensor data extracted as described above, the reference signal generation unit 104 generates a reference signal for each of the plurality of sensors from the acquired sensor data, and the preprocessing unit 106 performs a preprocessing operation including at least one of compression, normalization or symbolization of the sensor data and the reference signal.

First, the preprocessing unit 106 compresses the sensor data with a plurality of time intervals. Specifically, the preprocessing unit 106 compresses the sensor data by grouping the sensor data into a plurality of time intervals (w time intervals) and calculating a representative value of the sensor data in each grouping time interval. In some case, the representative value may be set as an average value or a median value of the sensor data in each grouped time interval. When the sensor data is compressed as such, there is an advantage in that a total volume of the sensor data can be decreased and noise in the data can be reduced. In such a case, for example, a SAX (Symbolic ApproXimation) algorithm may be used to determine the value of w, i.e., the number of intervals to use for grouping the sensor data, but embodiments of the present disclosure are not necessarily limited thereto.

An exemplary process for such compression of the sensor data will be described below. First, it is assumed that the sensor data sensed at periods of one second from a specific sensor are as follows.

3.5, 3.8, 3.9, 4.1, 4.5, 4.7, 4.8, 4.8, 4.8, 4.7, 4.8, 4.9, . . .

The sensor data is divided into four time intervals (w=4) and an average value is calculated for each interval, as shown in the following.

(3.5+3.8+3.9)/3=3.7 Period 1

(4.1+4.5+4.7)/3=4.4 Period 2

(4.8+4.8+4.8)/3=4.8 Period 3

(4.7+4.8+4.9)/3=4.8 Period 4

That is, in the above example, the sensor data may be compressed as follows.

3.7, 4.4, 4.8, 4.8

Then, the reference signal generation unit 104 generates the reference signal from the compressed sensor data. In an exemplary embodiment of the present disclosure, the reference signal refers to a signal used as a reference in calculating a distance, of the sensor data, for each sensor.

A process of generating the reference signal at the reference signal generation unit 104 will now be described. First, the reference signal generation unit 104 classifies the compressed sensor data for each sensor into a good group and a bad group based on information regarding whether the product is determined to be defective or non-defective. In other words, the sensor data generated in the course of fabricating the product determined to be good is included in the good group, and the sensor data generated in the course of fabricating the product determined to be bad is included in the bad group.

Then, the reference signal generation unit 104 generates the reference signal by calculating either an average value or a median value of the sensor data belonging to the good group for each of the (w) time intervals. In other words, in an exemplary embodiment of the present disclosure, the reference signal may be defined as the average value or the median value of the sensor data belonging to the good group for each interval.

Meanwhile, the reference signal generation unit 104 may be configured to remove any outliers from the good group before generating the reference signal. An “outlier” is sensor data that erratically deviates from the other sensor data belonging to the good group. Since such outliers are generally generated in an unusual situation, such as temporary failure of sensors or equipment, the reference signal would be rather distorted unless the outlier is excluded. Removing the outlier before generating the reference signal would then result in improved accuracy of the reference signal.

Specifically, the reference signal generation unit 104 may be configured to calculate a distribution of the data start time or the data end time of the sensor data belonging to the good group, and to remove the sensor data for which the data start time and/or the data end time is not included in a predetermined normal range, when there is such sensor data. In this case, the normal range may be calculated using at least one of an average value or a standard deviation of the data start time or the data end time of the sensor data included in the good group.

For example, if the average value of the data start time of the sensor data included in the good group is m and the standard deviation thereof is s, the normal range of the data start time may be determined as shown in equation (2) below:

m−3s≦data start time≦m+3s [Equation 2]

In other words, the reference signal generation unit 104 may generate the reference signal using only sensor data that is not abnormal, i.e., other than data whose data start time is outside the above range, among the sensor data belonging to the good group. While only the normal range of the data start time is described in the above equation, that of the data end time can be calculated in a same way.

Then, the preprocessing unit 106 normalizes the compressed sensor data. Specifically, as shown in Equation 3, the preprocessing unit 106 may normalize the sensor data using an average and a variance of the reference signals:

$${y}_{i} = \frac{{x}_{i} - μ}{σ} \qquad [ Equation 3 ]$$

where xᵢ denotes an i-th sensor value of the sensor data, yᵢ denotes a normalized version of the i-th sensor value, μ denotes the average of the reference signal, and σ denotes the variance of the reference signal.

Then, the preprocessing unit 106 converts the normalized sensor value of the sensor data and the reference signal to a plurality of symbols according to a predetermined sensor value range (symbolization). Specifically, the preprocessing unit 106 may divide an entire interval in which the normalized sensor values are distributed into a plurality of sub-intervals (α sub-intervals) and provide each divided sub-interval with an individual symbol (e.g., an alphabet letter) to symbolize the sensor data. For example, the preprocessing unit 106 can divide the period in which the sensor values are distributed, using the following Equation 4:

$${y}_{i} = {Φ}^{- 1} ( \frac{i}{n} ) \qquad [ Equation 4 ]$$

where yᵢ denotes a threshold of an i-th sub-interval, n denotes the number of all sub-intervals, and Φ denotes a cumulative normal distribution.

For example, it is assumed that the normalized sensor data is as follows:

−0.3, −0.7, −0.2, 0.4, 0.8, . . .

When the sensor data is symbolized, as shown in Table 1 below, the above sensor data should be converted as follows:

TABLE 1

| Period | Symbol |
|---|---|
| greater than or equal to −1.0 and less than −0.5 | A |
| greater than or equal to −0.5 and less than 0 | B |
| greater than or equal to 0 and less than 0.5 | C |
| greater than or equal to 0.5 and less than 1.0 | D |

Symbolized sensor data: BABCD

Distance Table Generation and Sensor Detection

Once the preprocessing of the sensor data in the preprocessing unit 106 is complete, the sensor detection unit 108 calculates a distance between the preprocessed sensor data and the preprocessed reference signal, and detects one or more sensors having a correlation with a yield of the product using the calculated distance.

First, the sensor detection unit 108 calculates a distance (MDIST) between each sensor value of the preprocessed sensor data and the preprocessed reference signal. The distance may be calculated, for example, using following Equation 5:

$${MDIST}_{i} = \{ \begin{matrix}0 , & if {Q}_{i} = {P}_{i} \\ {y}_{max ( r , c ) - 1} - {y}_{min ( r , c )} , & otherwise\end{matrix} \qquad [ Equation 5 ]$$

Equation 5 is used for calculating the distance (MDISTᵢ) between i-th elements (Qi, Pi) of two time series datasets Q and P, each of which is represented by n symbols. In Equation 5, r and c denote a position of a row (r) and that of a column (c) of a lookup table consisting of Qᵢ and Pᵢ respectively. The MDIST shown in Equation 5 is an exemplary distance therebetween, and various distance measures such as Euclidean Distance may be used. When the distance between each sensor value and the reference signal is calculated as described above, or in some other manner, the sensor detection unit 108 generates a distance table using the distance value and the information regarding whether the product is determined to be defective or non-defective. In an exemplary embodiment of the present disclosure, the sensor detection unit 108 may generate two distance tables including a first distance table and a second distance table. In the first one of these distance tables, the distance between each sensor value and the reference signal in the respective time interval is recorded. For example, it is assumed below that, in time intervals I1, I2 and I3, the sensor values sensed by a pressure sensor and a temperature sensor in a process of fabricating wafer 1 and wafer 2, and the reference signal, are given as shown in Table 2 below.

TABLE 2

| | Pressure | | | Temperature | | | Whether the |
|---|---|---|---|---|---|---|---|
| | Interval | | | | | | wafer is good |
| Sensor | I1 | I2 | I3 | I1 | I2 | I3 | or bad |
| Reference signal | C | C | C | C | D | A | |
| Wafer 1 | C | C | B | C | D | B | GOOD |
| Wafer 2 | A | C | D | A | C | E | BAD |

In this case, the first distance table may be calculated as shown in Table 3 below.

TABLE 3

| | Pressure | | | Temperature | | | Whether the |
|---|---|---|---|---|---|---|---|
| | Interval | | | | | | wafer is good or |
| Sensor | I1 | I2 | I3 | I1 | I2 | I3 | bad |
| Wafer 1 | 0 | 0 | 1 | 0 | 0 | 1 | GOOD |
| Wafer 2 | 2 | 0 | 1 | 2 | 1 | 4 | BAD |

In the second distance table, a sum of the distances (MDIST) in the first distance table is recorded for each sensor. For example, the second distance table is generated from the distance table of Table 3, as shown in Table 4 below.

TABLE 4

| Sensor | Pressure | Temperature | Whether the wafer is good or bad |
|---|---|---|---|
| Wafer 1 | 1 | 1 | GOOD |
| Wafer 2 | 3 | 7 | BAD |

If the distance tables are generated as described above, then the sensor detection unit 108 generates a decision tree by applying a classification and regression tree (CART) algorithm to the distance tables. Specifically, the sensor detection unit 108 may apply the CART algorithm to the first distance table and the second distance table to generate two decision trees, respectively. In this case, the first distance table may be used to recognize which interval of the sensor data has an effect on the yield of the product, while the second distance table may be used to recognize which sensor generally has an effect on the yield of the product.

With the CART algorithm applied to the distance tables as described above, a Gini index is calculated for each sensor corresponding to a node of a decision tree. The Gini index indicates an effect of the sensor, corresponding to the node, on the yield of the product, meaning that the higher the Gini index, the greater the effect of the sensor on the yield of the product. Therefore, the sensor detection unit 108 may sort the sensors according to the Gini indexes derived from the application of the CART algorithm, and may thus detect a sensor whose Gini index is equal to or more than a predetermined value as a sensor having a high correlation with the yield of the product.

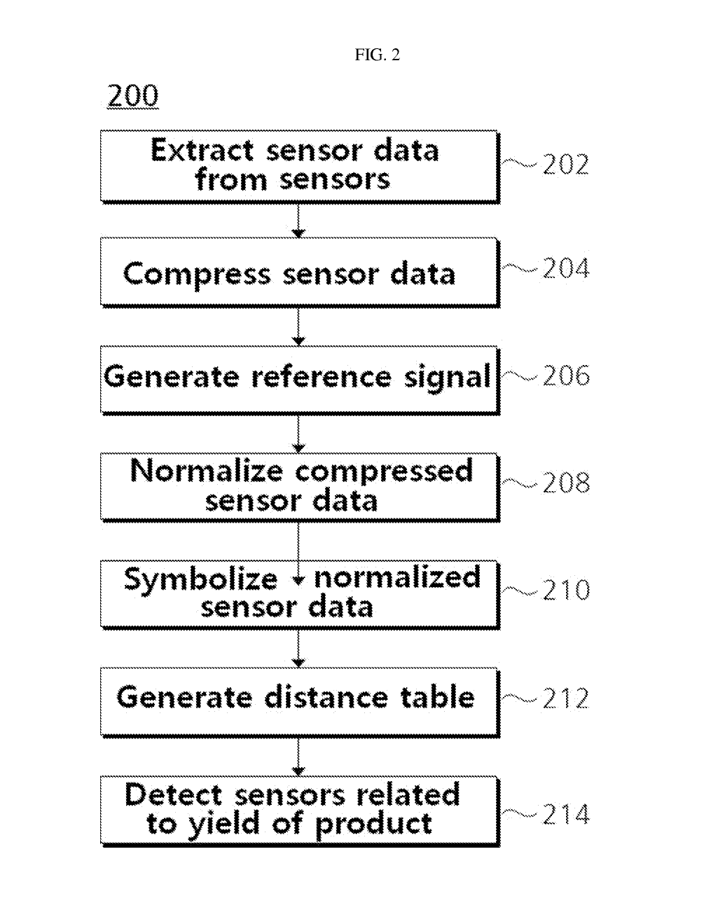

FIG. 2 is a flowchart for illustrating a product fabrication process analysis method 200 according to an exemplary embodiment of the present disclosure. First, the data extraction unit 102 extracts sensor data from a plurality of sensors arranged in equipment for fabricating a product (202). As described above, the extracting of the sensor data (202) may include correcting or filtering the sensor data based on the number of values missing from the sensor data. For example, when the number of values missing from the sensor data extracted from a specific sensor exceeds a predetermined threshold value, the data extraction unit 102 may remove the sensor data extracted from that specific sensor. Further, when the number of values missing from the sensor data related to a specific product exceeds a predetermined threshold value, the data extraction unit 102 may remove all the sensor data related to that specific product.

Then, the preprocessing unit 106 compresses the extracted sensor data (204). Specifically, the compressing of the extracted sensor data (204) may include grouping the sensor data into a plurality of time intervals, and calculating a representative value of the sensor data in each grouping time interval. In this case, the representative value may be either an average value or a median value of the sensor data in each grouping time interval.

Then, the reference signal generation unit 104 generates a reference signal for each of the plurality of sensors from the sensor data (206). In this case, the generating of the reference signal (206) may include grouping the compressed sensor data for each sensor into a good group and a bad group based on information regarding whether the product is determined to be defective or non-defective, and calculating either an average value or a median value of the sensor data belonging to the good group, for each time interval.

Further, the reference signal generation unit 104 may be configured to remove an outlier from the good group before generating the reference signal, as described above. In this case, the outlier refers to sensor data of which at least one of data start time and data end time is not included in a predetermined normal range, as already described above. The normal range may be calculated using either an average value or a standard deviation of the data start time or the data end time of the sensor data included in the good group.

With the reference signal generated as described above, the preprocessing unit 106 normalizes the compressed sensor data using an average and a variance of the reference signal (208), and converts a sensor value of the normalized sensor data, and the reference signal, to a plurality of symbols according to a predetermined sensor value range (210).

Then, the sensor detection unit 108 calculates a distance between the sensor data and the reference signal, generates a distance table using the calculated distance (212), and detects one or more sensors having a correlation with a yield of the product using the distance table (214). As described above, the sensor detection unit 108 may be configured to apply a classification and regression tree (CART) algorithm to the distance table and detect a sensor for which a Gini index derived from the application of the CART algorithm is equal to or more than a predetermined value as a sensor having a correlation with the yield of the product.

Meanwhile, exemplary embodiments of the present disclosure may include a computer-readable recording medium including a program for performing the methods described in the present specification in a computer. The computer-readable recording medium may include program instructions, local data files, and local data structures, alone or in combination. The medium may be specially designed and configured for the present disclosure, or well known and available to those skilled in the field of computer software. Examples of the computer-readable recording medium include magnetic media such as a hard disk, a floppy disk and a magnetic tape, optical recording media such as a CD-ROM and a DVD, magneto-optical media such as a floptical disk, and hardware devices, specially configured to store and execute program instructions, such as a ROM, a RAM, and a flash memory. Examples of the program instructions may include high-level language codes executable by a computer using an interpreter or the like, as well as machine language codes made by a compiler. Furthermore, an exemplary embodiment may include a device with a processor and a memory for using such a program and/or computer-readable medium.

According to embodiments of the present disclosure, when a yield analysis is performed for identifying a process that causes a defective product, it is advantageous to analyze fabrication process data by using original sensor data having time series characteristics, thereby precisely recognizing a factor that has an effect on a yield of the product.

Further, it is also advantageous to perform preprocessing on the sensor data having a huge volume and summarize the sensor data, thereby reducing the volume of the data and effectively removing noise introduced into the sensor data during the fabrication process. Accordingly, a technique is available for effectively analyzing the sensor data while exploiting the time series characteristics of the data as well.

While the present disclosure has been described above in detail through the representative exemplary embodiments, it will be apparent to those skilled in the art that various modifications can be made to the above-described exemplary embodiments of the present disclosure without departing from the spirit or scope of the present disclosure.

Thus, it is intended that the present disclosure cover all such modifications that fall within the scope of the appended claims and their equivalents.

What is claimed is:

1. A yield analysis system comprising a computer executing program commands and implementing:
a data extraction unit configured to extract respective sensor data from each sensor of a plurality of sensors arranged in equipment for fabricating a product;
a reference signal generation unit configured to generate a reference signal, for said each sensor, from the sensor data; and
a sensor detection unit configured to detect one or more sensors of the plurality of sensors having a correlation, with a yield of the product, using the sensor data and the reference signal.

2. The system according to claim 1, wherein the data extraction unit is further configured to carry out one of a correction operation and a filter operation with respect to the sensor data, based on a number of values missing from the sensor data.

3. The system according to claim 2, wherein the data extraction unit is further configured to remove the respective sensor data, extracted from a specific sensor of the plurality of sensors, when the number of values missing from the respective extracted sensor data exceeds a predetermined threshold value.

4. The system according to claim 2, wherein the data extraction unit is further configured to remove the sensor data related to a specific product when the number of values missing from the sensor data related to the specific product exceeds a predetermined threshold value.

5. The system according to claim 1, wherein the sensor detection unit is further configured to calculate a distance between the respective sensor data and the reference signal, and detects one or more of the plurality of sensors having a correlation with the yield of the product based on the calculated distance.

6. The system according to claim 1, further comprising a preprocessing unit configured to perform preprocessing with respect to the sensor data and the reference signal, including at least one of a compression operation, a normalization operation, and a symbolization operation.

7. The system according to claim 6, wherein the preprocessing unit is further configured to compress the sensor data by:
grouping the sensor data into a plurality of time intervals; and
calculating a representative value of the sensor data in each grouping time interval.

8. The system according to claim 7, wherein the representative value is one of an average value and a median value of the sensor data, in each grouped time interval.

9. The system according to claim 7, wherein the reference signal generation unit is further configured to:
generate the reference signal by grouping the compressed sensor data from each sensor into one of a good group and a bad group, based on information indicating whether the product is determined to be defective; and
calculate one of an average value and a median value of the sensor data belonging to the good group, for each time interval.

10. The system according to claim 9, wherein the reference signal generation unit is further configured to remove an outlier from the good group, before generating the reference signal.

11. The system according to claim 10, wherein at least one of a data start time and a data end time of the outlier is not included in a predetermined normal range.

12. The system according to claim 11, wherein the normal range is calculated using at least one of an average value and a standard deviation of one of the data start time and the data end time of the sensor data included in the good group.

13. The system according to claim 6, wherein the preprocessing unit is further configured to:
normalize the compressed sensor data using an average and a variance of the reference signal; and
convert a sensor value of the normalized sensor data and the reference signal to a plurality of symbols according to a predetermined sensor value range.

14. The system according to claim 13, wherein the sensor detection unit is further configured to generate a decision tree by:
generating a distance table using the symbolized sensor data and reference signal, and yield decision information regarding the product; and
applying a classification and regression tree (CART) algorithm to the distance table.

15. The system according to claim 14, wherein the sensor detection unit is further configured to detect, as a sensor having a correlation with the yield of the product, a sensor for which a Gini index, derived from the application of the CART algorithm, is at least a predetermined value.

16. A yield analysis method comprising:
extracting, by a data extraction unit, sensor data from each sensor of a plurality of sensors arranged in equipment for fabricating a product;
generating, by a reference signal generation unit, a reference signal for said each sensor, from the sensor data; and
detecting, by a sensor detection unit, one or more sensors of the plurality of sensors having a correlation with a yield of the product, using the sensor data and the reference signal.

17. The method according to claim 16, wherein the extracting of the sensor data includes carrying out one of a correcting operation and a filtering operation with respect to the sensor data, based on a number of values missing from the sensor data.

18. The method according to claim 17, further comprising removing the sensor data extracted, from a specific sensor of the plurality of sensors, when the number of values missing from the respective extracted sensor data exceeds a predetermined threshold value.

19. The method according to claim 17, further comprising removing the sensor data related to the specific product when the number of values missing from the sensor data related to the specific product exceeds a predetermined threshold value.

20. The method according to claim 16, wherein the detecting of the sensors includes calculating a distance between the respective sensor data and the reference signal, and detecting one or more of the plurality of sensors having a correlation with the yield of the product based on the calculated distance.

21. The method according to claim 16, further comprising, after the extracting of the sensor data and before the generating of the reference signal, compressing the extracted sensor data using a preprocessing unit.

22. The method according to claim 21, wherein the compressing of the sensor data includes:
grouping the sensor data into a plurality of time intervals; and
calculating a representative value of the sensor data in each grouping time interval.

23. The method according to claim 22, wherein the representative value is one of an average value and a median value of the sensor data, in each grouped time interval.

24. The method according to claim 21, wherein the generating of the reference signal for each sensor includes:
grouping the compressed sensor data from each sensor into one of a good group and a bad group, based on information indicating whether the product is determined to be defective; and
calculating one of an average value and a median value of the sensor data belonging to the good group, for each time interval.

25. The method according to claim 24, wherein the grouping of the compressed sensor data includes removing an outlier from the good group.

26. The method according to claim 25, wherein at least one of a data start time and a data end time of the outliner is not included in a predetermined normal range.

27. The method according to claim 26, wherein the normal range is calculated using at least one of an average value and a standard deviation of one of the data start time and the data end time of the sensor data included in the good group.

28. The method according to claim 21, further comprising, before the detecting of the one or more sensors:
normalizing, by the preprocessing unit, the compressed sensor data using an average and a variance of the reference signal; and
converting, by the preprocessing unit, a sensor value of the normalized sensor data and the reference signal to a plurality of symbols according to a predetermined sensor value range.

29. The method according to claim 28, wherein the detecting of the one or more sensors includes:
generating a distance table using the symbolized sensor data and reference signal and yield decision information regarding the product; and
applying a CART (Classification And Regression Tree) algorithm to the distance table.

30. The method according to claim 29, wherein the detecting of the one or more sensors further includes detecting, as a sensor having a correlation with the yield of the product, a sensor for which a Gini index derived from the application of the CART algorithm is at least a predetermined value.

31. A device comprising:
one or more processors;
a memory; and
one or more programs stored in the memory, the one or more programs being configured to be executed by the one or more processors;
wherein the one or more programs enable the one or more processors to carry out operations, comprising:
extracting sensor data from each sensor of a plurality of sensors arranged in equipment for fabricating a product;
generating a reference signal for said each sensor from the sensor data; and
detecting one or more sensors of the plurality of sensors having a correlation with a yield of the product, using the sensor data and the reference signal.
